(19) United States
(12) Patent Application Publication
(10) Pub. No.: US 2023/0146397 A1
(43) Pub. Date: May 11, 2023

(54) SEMICONDUCTOR DEVICE

(71) Applicant: RENESAS ELECTRONICS CORPORATION, Tokyo (JP)

(72) Inventor: Takahiro MORI, Tokyo (JP)

(21) Appl. No.: 17/932,120

(22) Filed: Sep. 14, 2022

(30) Foreign Application Priority Data
Nov. 8, 2021 (JP) 2021-181635

(51) Int. Cl. H01L 29/06; H01L 29/08; H01L 29/78

(52) U.S. Cl. CPC H01L 29/0653; H01L 29/0878; H01L 29/7816

(57) ABSTRACT

In a LDMOSFET 100, an “STI structure 11” provided in a drain region including a high concentration drain region 10 and a drift region 12 including the high concentration drain region 10 has a slit region 11A extending in a x-direction, and in plan view, the “STI structure 11” is interposed between the slit region 11A and the high concentration drain region 10.

### CROSS-REFERENCE TO RELATED APPLICATIONS

The disclosure of Japanese Patent Application No. 2021-181635 filed on Nov. 8, 2021, including the specification, drawings and abstract is incorporated herein by reference in its entirety.

### BACKGROUND

The present invention relates to a semiconductor device and, for example, to techniques valid for application to semiconductor device including laterally diffused MOSFET (LDMOSFET: Laterally Diffused Metal Oxide Semiconductor Field Effect Transistor).

There are disclosed techniques listed below.
[Non-Patent Document 1] J. Jang, K. Cho et al., “Interdigitated LDMOS,” Proceedings of The 25th International Symposium on Power Semiconductor Devices & ICs, pp. 245-248.

Non-Patent Document 1 discloses a technique for improving the breakdown voltage of LDMOSFET by devising the structure of LDMOSFET to relax the electric field in the electric field concentration region.

### SUMMARY

In LDMOSFET, there is a technique to improve the breakdown voltage by forming a “STI structure” in the drift region. However, if employing the “STI structure”, while it is possible to improve the breakdown voltage, the on-resistance is increased. Therefore, in order to reduce the on-resistance, a technique of providing a slit region in the “STI structure” has been investigated. In this regard, while it is possible to reduce the on-resistance by forming a slit region, an electric field concentration region in which the electric field intensity is large is formed in the drift region exposed from the slit region, then the breakdown voltage reduction of LDMOSFET becomes apparent due to this electric field concentration region.

In this regard, if it is possible to relax the electric field in the electric field concentration region generated in the drift region exposed from the slit region, it is considered that it is possible to suppress the breakdown voltage reduction of LDMOSFET. Therefore, from the viewpoint of suppressing the breakdown voltage reduction, it is desired to devise to relax the electric field in the electric field concentration region generated in the drift region exposed from the slit region.

In a semiconductor device (LDMOSFET) according to one embodiment, an isolation region provided in a drain region including a high concentration drain region and a low concentration drain region including the high concentration drain region has a slit region extending in a first direction, and the isolation region is interposed between the slit region and the high concentration drain region in plan view.

In a semiconductor device (LDMOSFET) according to one embodiment, an isolation region provided in a drain region including a high concentration drain region and a low concentration drain region including a high concentration drain region has a slit region extending in a first direction, and a connection region between a source region side end portion of a slit diffusion region exposed from the slit region and the low concentration drain region is exposed from a gate electrode in plan view.

According to one embodiment, it is possible to suppress the breakdown voltage reduction of the semiconductor device.

### BRIEF DESCRIPTION OF THE DRAWINGS

FIG. 1 is a figure showing a planar layout of an LDMOSFET in a first related art.

FIG. 2 is a cross-sectional view taken along line A-A in FIG. 1.

FIG. 3 is a figure showing a planar layout of an LDMOSFET in a second related art.

FIG. 4 is a cross-sectional view taken along line A-A in FIG. 3.

FIG. 5 is a figure schematically showing an electric field distribution in a slit diffusion region.

FIG. 6 is a figure for explaining the concept of the first basic idea.

FIG. 7 is a figure for explaining the concept of the second basic idea.

FIG. 8 is a figure showing a planar layout of an LDMOSFET in embodiments.

FIG. 9 is a cross-sectional view taken along line A-A in FIG. 8.

FIG. 10 is a cross-sectional view taken along line B-B in FIG. 8.

FIG. 11 is a graph showing the relationship between the dimension “D” and the breakdown voltage of LDMOSFET when employing only the first characteristic point.

FIG. 12 is a graph showing the relationship between the dimension “D” and the on-resistance of LDMOSFET when employing only the first characteristic point.

FIG. 13 is a graph showing the relationship between the dimension “D” and the breakdown voltage of LDMOSFET when employing both the first characteristic point and the second characteristic point.

FIG. 14 is a graph showing the relationship between the dimension “D” and the on-resistance of LDMOSFET when employing both the first characteristic point and the second characteristic point.

FIG. 15 is a figure showing a planar layout of an LDMOSFET in first modified example.

FIG. 16 is a figure showing a planar layout of an LDMOSFET in second modified example.

FIG. 17 is a figure showing a planar layout of an LDMOSFET in third modified example.

FIG. 18A and FIG. 18B are figures each showing a simulation result of the generation frequency of the impact ionization phenomenon in the slit diffusion region.

FIG. 19 is a figure showing a planar layout of an LDMOSFET in fourth modified example.

FIG. 20 is a cross-sectional view showing the manufacturing process of the semiconductor device in one embodiment.

FIG. 21 is a cross-sectional view showing the manufacturing process of the semiconductor device following FIG. 20.

FIG. 22 is a cross-sectional view showing the manufacturing process of the semiconductor device following FIG. 21.

FIG. 23 is a cross-sectional view showing the manufacturing process of the semiconductor device following FIG. 22.

FIG. 24 is a cross-sectional view showing the manufacturing process of the semiconductor device following FIG. 23.

FIG. 25 is a cross-sectional view showing the manufacturing process of the semiconductor device following FIG. 24.

FIG. 26 is a cross-sectional view showing the manufacturing process of the semiconductor device following FIG. 25.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

### Investigation of Improvement

Firstly, the related art which is a premise for deriving the technical idea in the present embodiment will be described. The “related art” referred to in this specification is not a known technique, but is a technique having a problem found by the present inventors and is a technique which is a premise of the present invention.

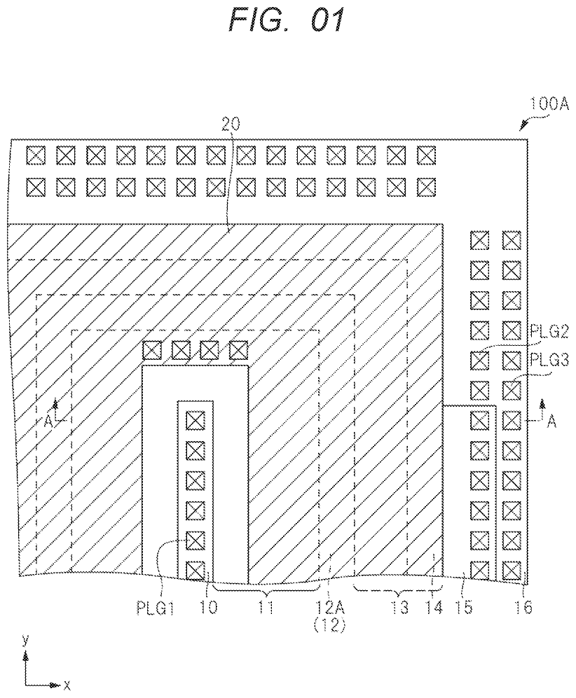

FIG. 1 is a figure showing a planar layout of an LDMOSFET 100A in the first related art. In FIG. 1, the LDMOSFET 100A has a high concentration drain region 10 extending in the y-direction (second direction), and a plurality of plugs PLG1 are connected to the high concentration drain region 10. The LDMOSFET 100A has a drift region 12 (low concentration drain region) formed to surround the high concentration drain region 10. The impurity concentration of the drift region 12 is lower than that of the high concentration drain region 10.

Furthermore, the LDMOSFET 100A has an isolation region which is in contact with the high concentration drain region 10 and the drift region 12 and is formed so as to be sandwiched between an end region 12A of the drift region 12 in a x-direction intersecting the y-direction (first direction) and the high concentration drain region 10 in plan view. This isolation region is “STI structure 11”.

Subsequently, as shown in FIG. 1, the LDMOSFET 100A has a body region 14 arranged away from the drift region 12, and a source region 15 provided outside the body region 14. At this time, a region located between the drift region 12 and the source region 15 functions as a channel region 13. Then, the LDMOSFET 100A further has a body contact region 16 provided outside the source region 15.

Here, a plurality of plugs PLG2 are connected to the source region 15, and a plurality of plugs PLG3 are connected to the body contact region 16. Then, as shown in FIG. 1, the LDMOSFET 100A has a gate electrode 20 (diagonal region in FIG. 1) formed so as to planarly overlap with a portion of the “STI structure 11”, the end region 12A of the drift region 12 and the channel region 13.

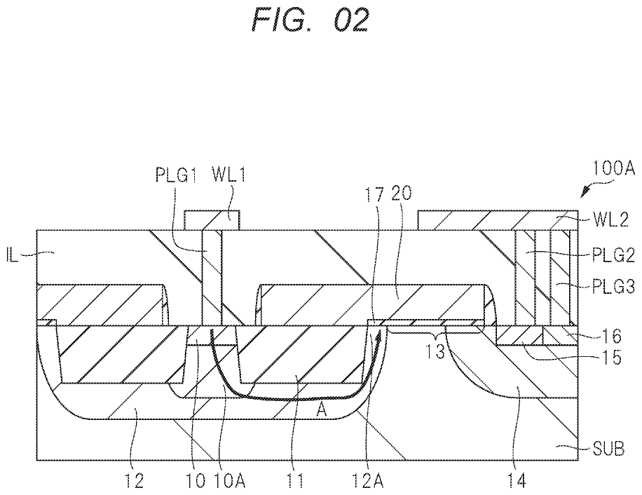

FIG. 2 is a cross-sectional view taken along line A-A in FIG. 1.

In FIG. 2, the high concentration drain region 10 is formed in a semiconductor substrate SUB, and a buffer region 10A is formed so as to include the high concentration drain region 10. Further, the drift region 12 is formed so as to include the buffer region 10A. Here, the “drain region” is constituted by the high concentration drain region 10, the buffer region 10A and the drift region 12.

The “STI structure 11” is formed so as to be sandwiched between the high concentration drain region 10 and the end region 12A of the drift region 12. Furthermore, the body region 14 is formed in a region away from the end region 12A of the drift region 12, the source region 15 and the body contact region 16 is formed so as to be included in the body region 14. Here, the surface region of the semiconductor substrate SUB sandwiched between the end region 12A of the drift region 12 and the source region 15 is the channel region 13.

Next, the gate electrode 20 is formed on a portion of the “STI structure 11”, the end region 12A of the drift region 12 and the channel region 13, in particular, the gate electrode 20 is formed on the end region 12A of the drift region 12 and the channel region 13 via a gate dielectric film 17. Subsequently, an interlayer dielectric layer IL is formed on the semiconductor substrate SUB so as to cover the gate electrode 20, and a plurality of plugs penetrating the interlayer dielectric layer IL is formed in the interlayer dielectric layer IL. For example, as shown in FIG. 2, the plurality of plugs include a plug PLG1 that is electrically connected to the high concentration drain region 10, a plug PLG2 that is electrically connected to the source region 15, and a plug PLG3 that is electrically connected to the body contact region 16. Then, for example, the plug PLG1 is electrically connected to wiring WL1 formed on the interlayer dielectric layer IL. On the other hand, the plug PLG2 and the plug PLG3 are electrically connected to wiring WL2 formed on the interlayer dielectric layer IL.

In this way, the LDMOSFET 100A in the first related art is configured. Here, in the LDMOSFET 100A, as shown in FIG. 2, “STI structure 11” constituting the isolation region is provided in the drift region 12. Therefore, the current path A from the high concentration drain region 10 to the source region 15 will pass through the path (see arrow in FIG. 2) to detour around the “STI structure 11”. Consequently, according to the LDMOSFET 100A in the first related art, since the current path between the high concentration drain region 10 and the source region 15 becomes long, it is possible to ensure the breakdown voltage between the high concentration drain region 10 and the source region 15.

However, the fact that the current path between the high concentration drain region 10 and the source region 15 becomes longer means that the on-resistance increases. Therefore, in the LDMOSFET 100A in the first related art, while it is possible to improve the breakdown voltage between the high concentration drain region 10 and the source region 15, there is also a disadvantage that the on-resistance is increased. That is, in the LDMOSFET, there is a relationship of trade-off between the improvement of the breakdown voltage and the reduction of the on-resistance, and in the LDMOSFET 100A in the first related art, while achieving both the improvement of the breakdown voltage and the reduction of the on-resistance, there is a room for improvement in response to the requirement of further reducing the on-resistance.

Therefore, the structure of the LDMOSFET capable of further reducing the on-resistance while achieving both the improvement of the breakdown voltage and the reduction of the on-resistance has been investigated.

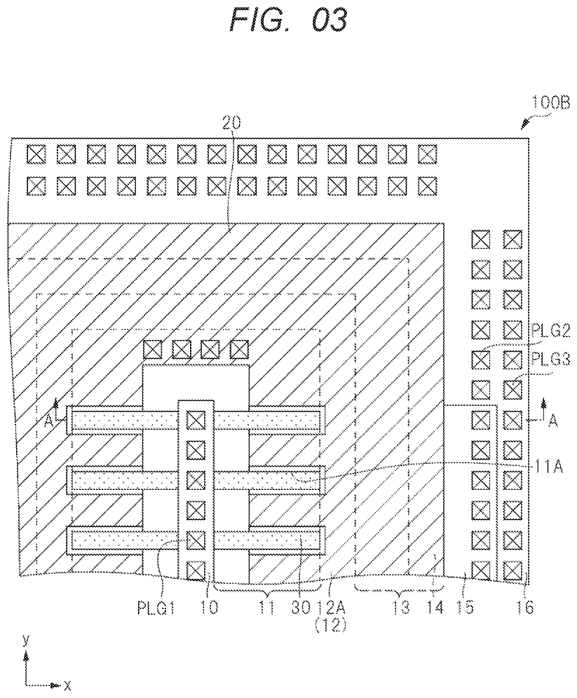

FIG. 3 is a figure showing a planar layout of an LDMOSFET 100B in a second related art. In FIG. 3, in the LDMOSFET 100B of the second related art, a slit region 11A is formed in the “STI structure 11”. The slit region 11A extends in the x-direction and is connected to the high concentration drain region 10 and the end region 12A of the drift region 12. The drain region is exposed from the slit region 11A. In particular, in this specification, a drain region exposed from the slit region 11A is referred to as a slit diffusion region 30 (region with dots).

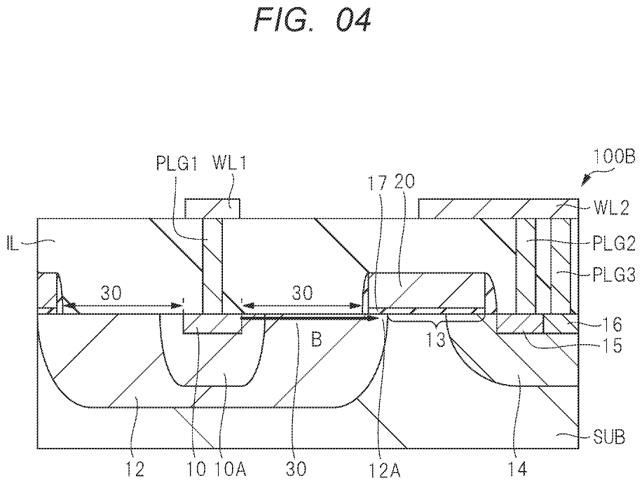

FIG. 4 is a cross-sectional view taken along line A-A in FIG. 3.

As shown in FIG. 4, in the second related art, a slit diffusion region 30 is formed between the high concentration drain region 10 and the end region 12A of the drift region 12. As a result, in the second related art, not only the same current path A as the first related art shown in FIG. 2, the current path B passing through the slit diffusion region 30 shown in FIG. 4 will also be present. Thus, in the second related art, while it is possible to improve the breakdown voltage basically by the detour path by the current path A, the auxiliary current path B (shortest path) contributes to reduce the on-resistance. That is, according to the second related art, while achieving both the improvement of the breakdown voltage and the reduction of the on-resistance, it is possible to cope with a request to further reduce the on-resistance. That is, the second related art is considered to be useful as a structure that overcomes the room for improvement existing in the first related art.

### Knowledge Found by Present Inventors

However, by the present inventors have investigated the structure of the LDMOSFET 100B in the second related art, it was found that the electric field concentration region in which the electric field intensity is large is formed in the slit diffusion region 30 connecting the high concentration drain region 10 with the end region 12A of the drift region 12 and that the breakdown voltage reduction of the LDMOSFET due to the electric field concentration region is revealed.

Hereinafter, novel knowledge found by the present inventors will be described.

FIG. 5 is, for example, a figure schematically showing the electric field distribution of the slit diffusion region by simulation. In FIG. 5, when a high voltage is applied between the high concentration drain region 10 and the source region (not shown), in the slit diffusion region 30 connecting the high concentration drain region 10 with the end region 12A of the drift region 12, it can be seen that there is an electric field concentration region CP1 indicated by “black region” and an electric field concentration region CP2 indicated by “black region”.

In the second related art in which such the electric field concentration region CP1 and the electric field concentration region CP2 are present, the electric field concentration region CP1 and the electric field concentration region CP2 described above are “weak point”, the breakdown voltage reduction of the LDMOSFET 100B is revealed. That is, in the second related art, although the slit diffusion region 30 is provided in order to reduce the on-resistance of the LDMOSFET 100B, according to the investigation of the present inventors, it was found that the breakdown voltage reduction of the LDMOSFET 100B is caused as a result of the electric field concentration region is formed in the slit diffusion region 30.

In this regard, it is considered that it is possible to suppress the breakdown voltage reduction of the LDMOSFET 100B if it is possible to relax the electric field in the electric field concentration region CP1 and the electric field concentration region CP2 generated in the slit diffusion region 30. Therefore, from the viewpoint of suppressing the breakdown voltage reduction of the LDMOSFET 100B, it is desired to devise to relax the electric field in the electric field concentration region CP1 and the electric field concentration region CP2 generated in the slit diffusion region 30.

Therefore, in the present embodiment, a devise is provided to overcome the room for improvement existing in the second related art. Hereinafter, the technical idea in the present embodiment to which this devise is applied will be described.

### Basic Idea in Present Embodiment

Since the basic idea in the present embodiment includes the first basic idea and the second basic idea, each of the first basic idea and the second basic idea will be described below.

### First Basic Idea

The first basic idea is to remove the electric field concentration region where electric field concentration is generated from the slit diffusion region. That is, the first basic idea is the idea of removing a portion of the slit diffusion region where electric field concentration is generated. Thus, since the electric field concentration region is removed from the slit diffusion region, there is no electric field concentration region in the slit diffusion region. This means that there is no region to be a weak point of the breakdown voltage reduction in the slit diffusion region, thereby, it is possible to suppress the breakdown voltage reduction of the LDMOSFET.

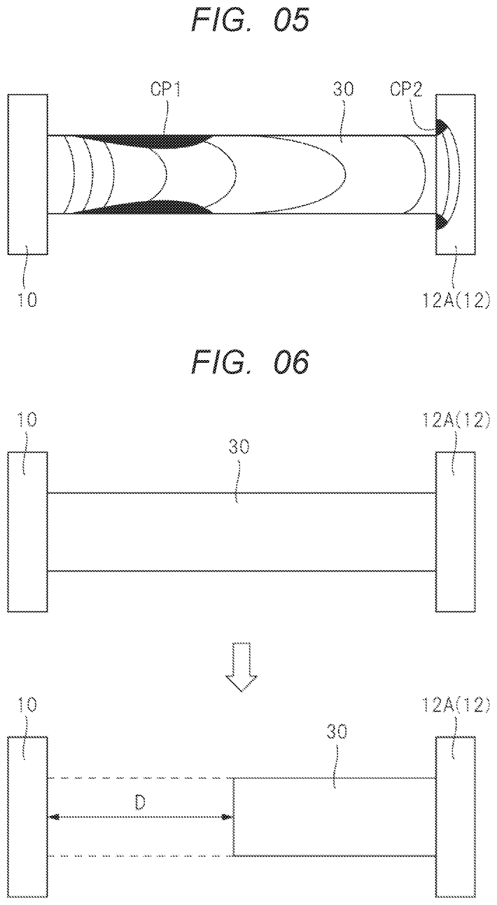

FIG. 6 is a figure for explaining the concept of the first basic idea.

First, as shown in FIG. 5, the electric field concentration region CP1 is generated in the slit diffusion region 30. Therefore, in the first basic idea, for example, as shown in FIG. 6, a portion of the slit diffusion region 30 including the electric field concentration region CP1 is removed. That is, the concept of the first basic idea is to suppress the breakdown voltage reduction caused by the electric field concentration region CP1, by removing a portion of the slit diffusion region 30 including the electric field concentration region CP1.

### Second Basic Idea

Next, the second basic idea is the idea of removing a portion of the gate electrode that planarly overlaps with the slit diffusion region in plan view. In other words, the second basic idea can be said to be the idea of providing a notch portion in the gate electrode planarly overlapping the slit diffusion region in plan view. Thus, it is possible to suppress the electric field concentration caused by a steep potential gradient based on the potential difference between the slit diffusion region and the gate electrode.

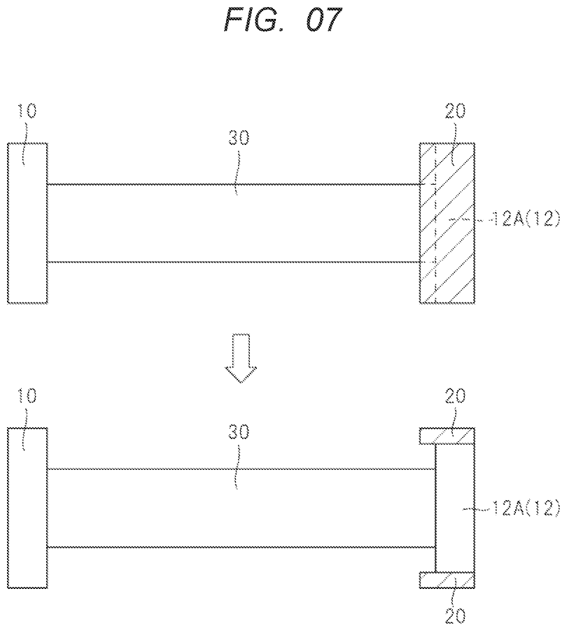

FIG. 7 is a figure for explaining the concept of the second basic idea.

As shown in the upper view of FIG. 7, the slit diffusion region 30 is provided so as to connect the high concentration drain region 10 and the end region 12A of the drift region 12. At this time, the connection region between the end region 12A of the drift region 12 and the slit diffusion region 30 is covered with the gate electrode 20.

Here, since a high positive voltage is applied to the high concentration drain region 10, a positive voltage is also applied to the slit diffusion region 30 which is connected to the high concentration drain region 10. On the other hand, for example, when LDMOSFET is turned off, 0 V (ground potential) is applied to the gate electrode 20. Therefore, when LDMOSFET is turned off, in the connection region between the slit diffusion region 30 and the end region 12A of the drift region 12 shown in the upper view of FIG. 7, a high positive voltage is applied to the connection region itself while 0 V is applied to the gate electrode 20 covering the connection region.

As a result, in the connection region covered with the gate electrode 20, a large potential difference is generated between the gate electrode 20 covering the connection region. Therefore, in the connection region between the end region 12A of the drift region 12 and the slit diffusion region 30, a steep potential gradient based on the large potential difference described above is generated. As a result, for example, the electric field concentration region CP2 as shown in FIG. 5 is generated.

Therefore, in the second basic idea, for example, as shown in the lower view of FIG. 7, a portion of the gate electrode 20 is removed (providing a notch portion) such that the connection region between the end region 12A of the drift region 12 and the slit diffusion region 30 is not covered by the gate electrode 20. That is, the concept of the second basic idea is to suppress that a large potential difference is generated between the gate electrode 20 covering the connection region, by removing a portion of the gate electrode 20 planarly overlapping with the connection region in plan view. Thus, according to the basic idea, in the connection region, it is possible to suppress the generation of the electric field concentration region CP2 caused by the steep potential gradient, thereby, it is possible to suppress the breakdown voltage reduction caused by the electric field concentration region CP2.

In this specification, that the connection region between the end region 12A of the drift region 12 and the slit diffusion region 30 is not covered by the gate electrode 20 may be referred to that “the connection region between the end region 12A of the drift region 12 and the slit diffusion region 30 is exposed from the gate electrode 20”. That is, in this specification, the expression that “the connection region between the end region 12A of the drift region 12 and the slit diffusion region 30 is not covered with the gate electrode 20” and the expression that “the connection region between the end region 12A of the drift region 12 and the slit diffusion region 30 is exposed from the gate electrode 20” are used with the same meaning.

### Specific Configuration of LDMOSFET

Next, the configuration of the LDMOSFET embodying the above-described first basic idea and second basic idea will be described with reference to the drawings.

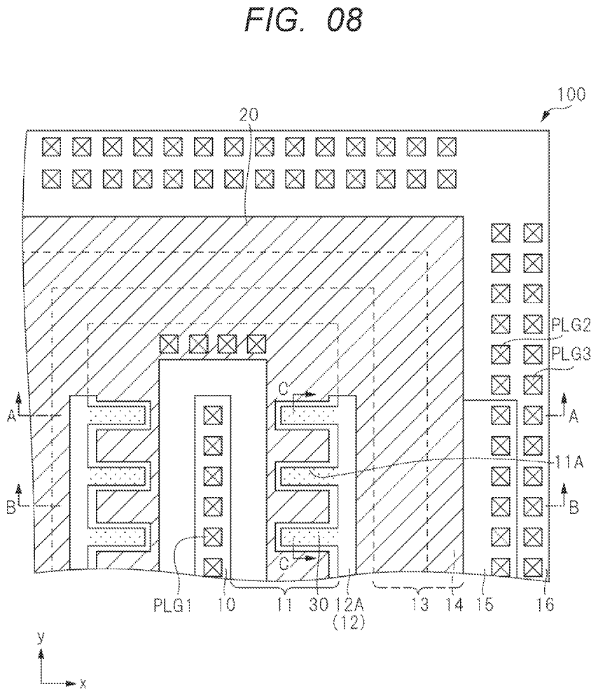

FIG. 8 is a figure showing a planar layout of the LDMOSFET 100 in the present embodiment. In FIG. 8, the LDMOSFET 100 has a high concentration drain region 10 extending in the y-direction (second direction), and a plurality of plugs PLG1 are connected to the high concentration drain region 10. The LDMOSFET 100 has a drift region 12 formed so as to surround the high concentration drain region 10. Furthermore, the LDMOSFET 100 has an isolation region which is in contact with the high concentration drain region 10 and the drift region 12 and is formed so as to be sandwiched between the end region 12A of the drift region 12 and the high concentration drain region 10 in the x-direction (first direction) intersecting the y-direction in plan view. This isolation region is “STI structure 11”.

Subsequently, as shown in FIG. 8, the LDMOSFET 100 has a body region 14 arranged away from the drift region 12, and a source region 15 provided outside the body region 14. At this time, a region located between the drift region 12 and the source region 15 functions as the channel region 13. Then, the LDMOSFET 100 further has a body contact region 16 provided outside the source region 15.

Here, a plurality of plugs PLG2 are connected to the source region 15, and a plurality of plugs PLG3 are connected to the body contact region 16. Then, as shown in FIG. 8, the LDMOSFET 100 has a gate electrode 20 (diagonal region in FIG. 8) formed so as to planarly overlap with at least a portion of “STI structure 11” and the channel region 13 in plan view.

Then, in the present embodiment, as shown in FIG. 8, a slit region 11A extending in the x-direction is provided in the “STI structure 11”, the slit diffusion region 30 which is in contact with the end region 12A of the drift region 12 and extends in the x-direction is exposed from the slit region 11A. At this time, in the LDMOSFET 100 in the present embodiment, a portion of the “STI structure 11” is interposed between the slit region 11A and the high concentration drain region 10. That is, in the present embodiment, unlike the second related art shown in FIG. 3, for example, the slit diffusion region 30 exposed from the slit region 11A is connected to the end region 12A of the drift region 12, but not to the high concentration drain region 10. In other words, the slit diffusion region 30 is planarly away from the high concentration drain region 10.

Next, as shown in FIG. 8, at least the connection region between the end region 12A of the drift region 12 and the slit diffusion region 30 is exposed from the gate electrode 20 in plan view. In other words, the connection region between the end region 12A of the drift region 12 and the slit diffusion region 30 does not planarly overlap with the gate electrode 20.

Furthermore, in the LDMOSFET 100 in the present embodiment, a plurality of slit regions 11A is formed in the “STI structure 11”, and the plurality of slit regions 11A is arranged side by side in the y-direction (second direction) in plan view. Then, in plan view, the slit diffusing region 30 is exposed from each of the plurality of slit regions 11A. At this time, the slit diffusion region 30 which is exposed from each of the plurality of slit regions 11A is exposed from the gate electrode 20 in plan view.

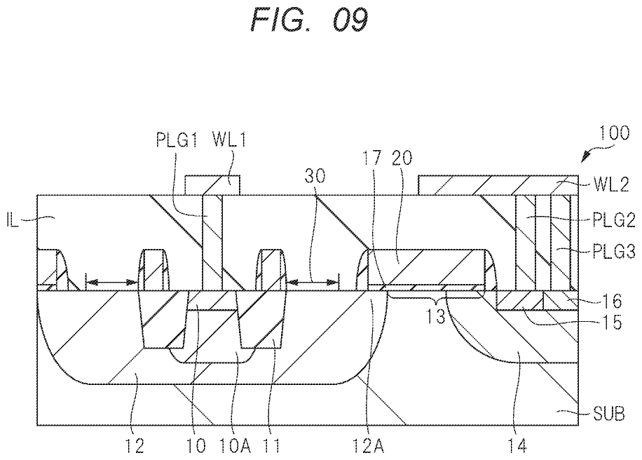

FIG. 9 is a cross-sectional view taken along the line A-A in FIG. 8.

In FIG. 9, the high concentration drain region 10 is formed in the semiconductor substrate SUB, and the buffer region 10A (medium concentration drain region) is formed so as to include the high concentration drain region 10. Further, the low concentration drain region 12 is formed so as to include the buffer region 10A. Here, the “drain region” is configured by the high concentration drain region 10, the buffer region 10A and the drift region 12.

Then, “STI structure 11” is formed so as to contact the high concentration drain region 10 and the drift region 12, and the slit diffusion region 30 is exposed so as to be sandwiched between the end region 12A of the drift region 12 and the “STI structure 11”.

Furthermore, the body region 14 is formed in a region away from the end region 12A of the drift region 12, and the source region 15 and the body contact region 16 are formed so as to be included in the body region 14. Here, the surface region of the semiconductor substrate SUB sandwiched between the end region 12A of the drift region 12 and the source region 15 is the channel region 13.

Next, the gate electrode 20 is formed on a portion of the “STI structure 11” and the channel region 13, in particular, the gate electrode 20 is formed on the channel region 13 via the gate dielectric film 17. On the other hand, in the present embodiment, the gate electrode 20 is not formed on the slit diffusion region 30 including the connection region between the end region 12A of the drift region 12 and the slit diffusion region 30. That is, in the present embodiment, the slit diffusion region 30 including the connection region between the end region 12A of the drift region 12 and the slit diffusion region 30 is exposed from the gate electrode 20.

Subsequently, the interlayer dielectric layer IL is formed on the semiconductor substrate SUB so as to cover the gate electrode 20, and a plurality of plugs penetrating the interlayer dielectric layer IL is formed in the interlayer dielectric layer IL. For example, as shown in FIG. 9, a plurality of plugs includes a plug PLG1 that is electrically connected to the high concentration drain region 10, a plug PLG2 that is electrically connected to the source region 15, and a plug PLG3 that is electrically connected to the body contact region 16. Then, for example, the plug PLG1 is electrically connected to wiring WL1 formed on the interlayer dielectric layer IL. On the other hand, the plug PLG2 and the plug PLG3 are electrically connected to wiring WL2 formed on the interlayer dielectric layer IL.

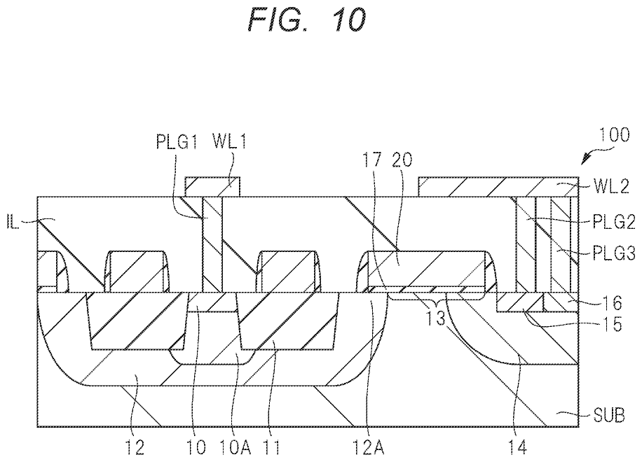

FIG. 10 is a cross-sectional view taken along line B-B in FIG. 8.

In FIG. 10, the high concentration drain region 10 is formed in the semiconductor substrate SUB, and the buffer region 10A (medium concentration drain region) is formed so as to include the high concentration drain region 10. Further, the low concentration drain region 12 is formed so as to include the buffer region 10A. The “STI structure 11” is formed so as to be in contact with the high concentration drain region 10 and the end region 12A of the drift region 12.

Furthermore, the body region 14 is formed in a region away from the end region 12A of the drift region 12, and the source region 15 and the body contact region 16 is formed so as to be included in the body region 14. Here, the surface region of the semiconductor substrate SUB sandwiched between the end region 12A of the drift region 12 and the source region 15 is the channel region 13.

Next, the gate electrode 20 is formed on a portion of the “STI structure 11” and the channel region 13, in particular, the gate electrode 20 is formed on the channel region 13 via the gate dielectric film 17. On the other hand, in the present embodiment, the gate electrode 20 is not formed on the connection region between the end region 12A of the drift region 12 and the STI structure 11. That is, in the present embodiment, the connection region between the end region 12A of the drift region 12 and the “STI structure 11” is exposed from the gate electrode 20. Also in FIG. 10, the structure relating to the interlayer dielectric layer IL (plug structure, etc.) is the same as in FIG. 9, a description thereof will be omitted.

In this way, the LDMOSFET 100 in the present embodiment is configured.

Incidentally, the semiconductor regions configuring the LDMOSFET 100, for example, are as follows: (1) Semiconductor substrate SUB; p⁻-type semiconductor substrate (2) High concentration drain region 10; n⁺-type semiconductor region (3) Buffer region 10A; n-type semiconductor region (4) Drift region 12; n⁻-type semiconductor region (5) Body region 14; p-type semiconductor region (6) Source region 15; n⁺-type semiconductor region (7) Body contact region 16; p⁺-type semiconductor region.

### Characteristics in Present Embodiment

Next, the characteristic points in the present embodiment will be described.

The first characteristic point in the present embodiment is, for example, as shown in FIG. 9, rather than the slit diffusion region 30 is extended so as to connect to the high concentration drain region 10, that the slit diffusion region 30 is away from the high concentration drain region 10 and a portion of the “STI structure 11” is interposed between the high concentration drain region 10 and the slit diffusion region 30. Thus, the first basic idea described above is embodied, the portion where the electric field concentration region is formed in the slit diffusion region 30 exposed from the slit region is removed and the portion is replaced with a portion of the “STI structure 11”. Therefore, according to the first characteristic point in the present embodiment, it is possible to suppress that the electric field concentration region is formed in the slit diffusion region 30 exposed from the slit region. That is, according to the first characteristic point, as a result of suppressing the formation of a region to be a weak point of the breakdown voltage reduction in the slit diffusion region 30, it is possible to suppress the breakdown voltage reduction of the LDMOSFET 100.

Next, the second characteristic point in the present embodiment is, for example, as shown in FIG. 8, that a portion of the gate electrode 20 is removed such that the connection region between the end region 12A of the drift region 12 and the slit diffusion region 30 is not covered by the gate electrode 20. In other words, the second characteristic point in the present embodiment is that the connection region between the end region 12A of the drift region 12 and the slit diffusion region 30 is exposed from the gate electrode 20.

Thus, according to the second characteristic point, it is possible to suppress that a large potential difference is generated between the gate electrode 20 covering the connection region (0 V: when turned-off) and the connection region (positive voltage). As a result, in the connection region, it is possible to suppress the generation of the electric field concentration region due to a steep potential gradient, thereby, it is possible to suppress the breakdown voltage reduction due to the electric field concentration region.

### Verification of Effect

In the following, according to the present embodiment, it will be described a verification result that can improve the breakdown voltage between the source region the drain region at the time of off-state by employing the first characteristic point and the second characteristic point described above while providing a slit diffusion region for reducing the on-resistance.

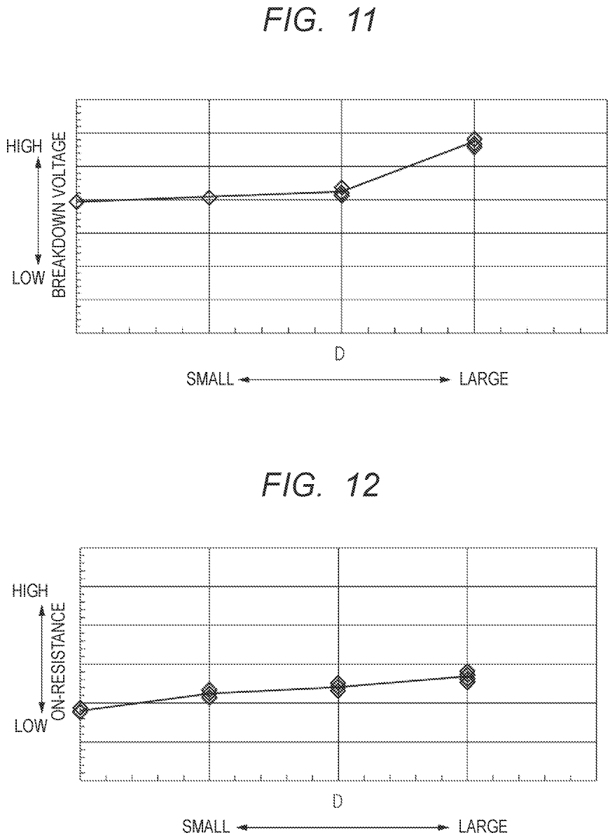

FIG. 11 is a graph showing the relationship between the dimension “D” and the breakdown voltage of LDMOSFET when employing only the first characteristic point. Further, FIG. 12 is a graph showing the relationship between the dimension “D” and the on-resistance of LDMOSFET when employing only the first characteristic point.

Here, the dimension “D” shows “D” shown in FIG. 6, and represents the length of the portion of the slit diffusion region to be removed. On the other hand, the breakdown voltage of LDMOSFET shows the breakdown voltage between the source region and the drain region at the time of off-state, and the on-resistance of LDMOSFET shows the resistance of LDMOSFET at the time of on-state.

As shown in FIG. 11, the larger the dimension “D”, it can be seen that the breakdown voltage is improved. That is, by increasing the portion of the slit diffusion region to be removed, it is possible to improve the breakdown voltage. However, as shown in FIG. 12, when increasing the dimension “D”, it can be seen that the on-resistance is increased. This is considered that the on-resistance is increased since the remaining portion of the slit diffusion region which contributes to the reduction of the on-resistance is reduced when increasing the dimension “D”.

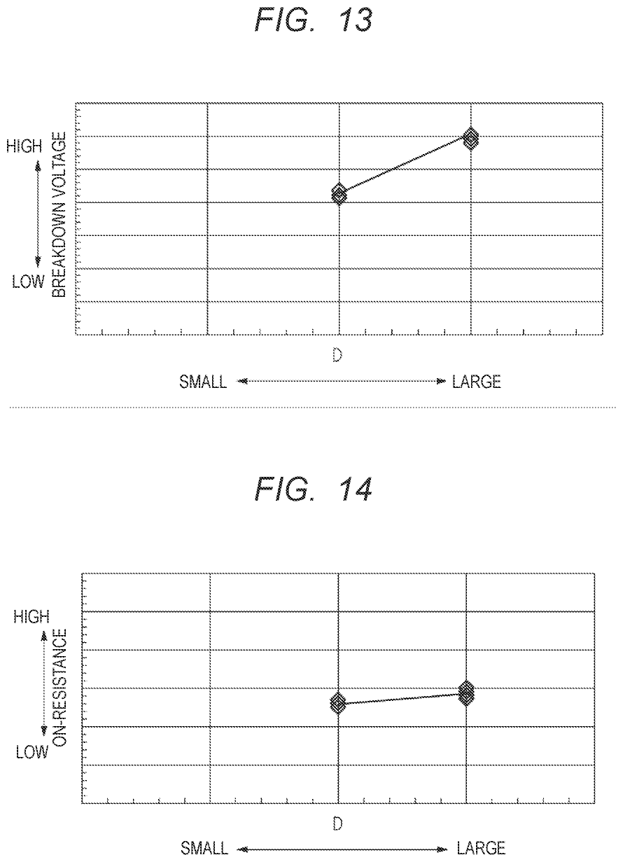

Next, FIG. 13 is a graph showing the relationship between dimension “D” and the breakdown voltage of the LDMOSFET when employing both the first characteristic point and the second characteristic point. Further, FIG. 14 is a graph showing the relationship between the dimension “D” and the on-resistance of the LDMOSFET when employing both the first characteristic point and the second characteristic point.

As shown in FIG. 13, if employing both the first characteristic point and the second characteristic point, when increasing the dimension “D”, it can be seen that it is possible to further improve the breakdown voltage. Therefore, from the viewpoint of improving the breakdown voltage, it is desirable to employ both the first characteristic point and the second characteristic point.

However, as shown in FIG. 14, when employing both the first characteristic point and the second characteristic point, it can be seen that the on-resistance is further increased. The following reasons are considered. That is, if not employing the second characteristic point, for example, as shown in FIG. 4, there is a gate electrode 20 on the end region 12A of the drift region 12. Here, when turning on the LDMOSFET, a positive voltage is applied to the gate electrode 20. Then, electrons, which are majority carriers, are attracted to the gate electrode 20 to form an accumulation region on the surface of the end region 12A, which is a n⁻-type semiconductor region. That is, the current path from the high concentration drain region 10 to the source region 15 includes the accumulation region having a low resistance. As a result, when the second characteristic point is not employed, the on-resistance is lowered.

In contrast, when employing the second characteristic point, as shown in FIG. 9, there is no gate electrode 20 on the end region 12A of the drift region 12. Therefore, even when LDMOSFET is turned on, the accumulation region is not formed on the surface of the end region 12A which is n⁻-type semiconductor region. As a result, since the accumulation region having low resistance is not formed in the current path from the high concentration drain region 10 to the source region 15, it is considered that the on-resistance is increased.

From the above, focusing on the improvement of the breakdown voltage regardless of the on-resistance, when employing only the first characteristic point (see FIG. 11) and when employing both the first characteristic point and the second characteristic point (see FIG. 13), it can be seen that the breakdown voltage of LDMOSFET can be improved.

### First Modified Example

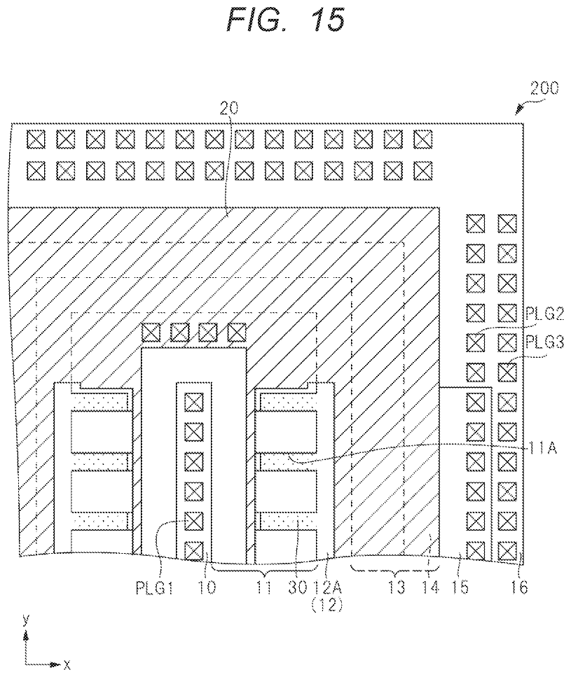

FIG. 15 is a figure showing a planar layout of an LDMOSFET 200 in the present first modified example. As shown in FIG. 15, the plurality of slit diffusion regions 30 which is arranged side by side in the y-direction may be configured to be integrally exposed from the gate electrode 20. That is, a portion of the gate electrode 20 may not be arranged between the slit diffusion regions 30 adjacent to each other.

### Second Modified Example

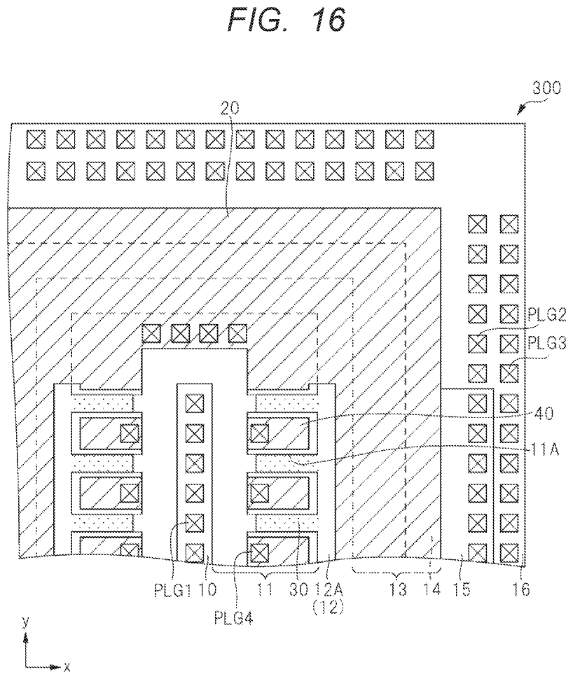

FIG. 16 is a figure showing a planar layout of an LDMOSFET 300 in the present second modified example. As shown in FIG. 16, the conductor pattern 40 provided between the slit diffusion regions 30 adjacent to each other may not be integrally formed with the gate electrode 20. In this case, for example, the conductor pattern 40 and the gate electrode 20 are electrically connected via a plug PLG4. At this time, in plan view, since the conductor pattern 40 is arranged between the slit diffusion regions 30 adjacent to each other in the y-direction among the plurality of slit diffusion regions 30, a plurality of conductor patterns 40 are arranged side by side in the y-direction.

### Third Modified Example

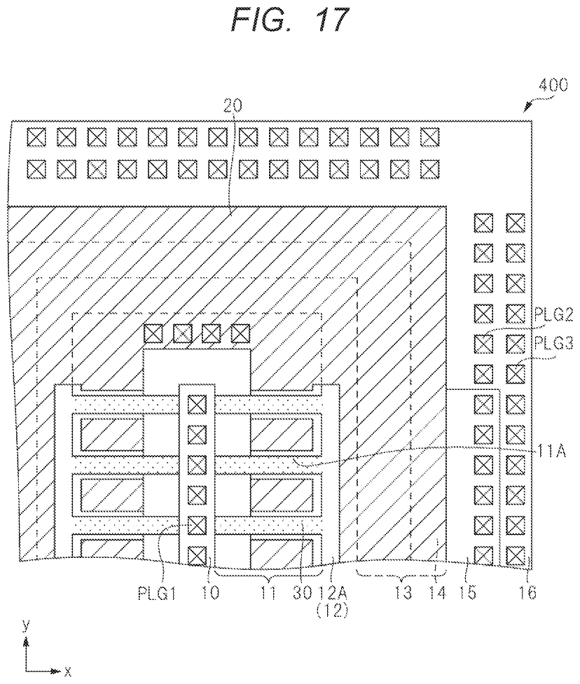

FIG. 17 is a figure showing a planar layout of an LDMOSFET 400 in the present third modified example. Here, when the first characteristic point and the second characteristic point in the present embodiment are compared (see FIGS. 11 to 14), the first characteristic point is useful from the viewpoint of improving the breakdown voltage more than the second characteristic point. On the other hand, the on-resistance increases in the first characteristic point than the second characteristic point. Therefore, in the case of device that the breakdown voltage is sufficiently improvement by the second characteristic point, in order to reduce the on-resistance, for example, as shown in FIG. 17, it may be configured to employ only the second characteristic point.

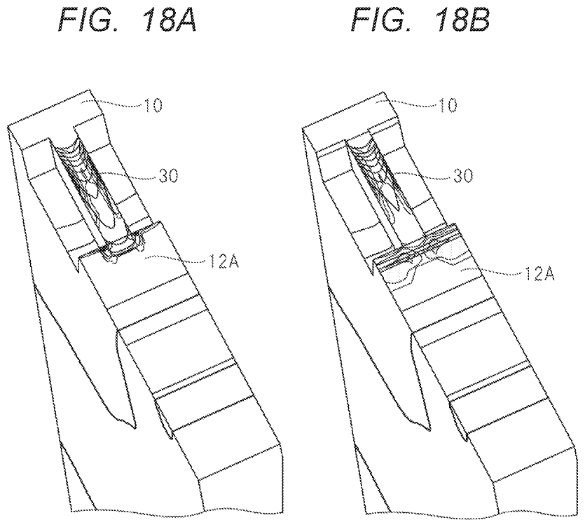

FIG. 18A and FIG. 18B are figures each showing a simulation result of the generation frequency of the impact ionization phenomenon in the slit diffusion region 30. In particular, FIG. 18A is a simulation result in a configuration that does not employ the second characteristic point (corresponding to the second related art), and FIG. 18B is a simulation result in a configuration that employs the second characteristic point (corresponding to the present third modified example). As shown in FIG. 18A, in a case of the second related art not employing the second characteristic point, focusing on the connection region between the slit diffusion region 30 and the end region 12A of the drift region 12, it can be seen that a region in which the generation frequency of impact ionization phenomena is high is present in this connection region. Here, the region where the generation frequency of impact ionization phenomena is high means the electric field concentration region, from the simulation results shown in FIG. 18A, it can be seen that the electric field concentration region described above becomes “weak point” and there is a high possibility that the breakdown voltage reduction of LDMOSFET becomes apparent in the second related art that does not employ the second characteristic point.

In contrast, as shown in FIG. 18B, in a case of the present third modified example employing the second characteristic point, focusing on the connection region between the slit diffusion region 30 and the end region 12A of the drift region 12, the generation frequency of impact ionization phenomena is dispersed and the region in which the generation frequency of impact ionization phenomena is high is reduced in this connection region. Here, the region where the generation frequency of impact ionization phenomena is high means the electric field concentration region, from the simulation result shown in FIG. 18B, it can be seen that the breakdown voltage reduction of LDMOSFET can be suppressed as a result of suppressing the generation of the electric field concentration region in the present third modified example employing the second characteristic point.

Thus, according to the present third modified example employing the second characteristic point, as a result that the electric field concentration in the connection region between the slit diffusion region 30 and the end region 12A of the drift region 12 can be relaxed, it is possible to suppress the breakdown voltage reduction of LDMOSFET.

### Fourth Modified Example

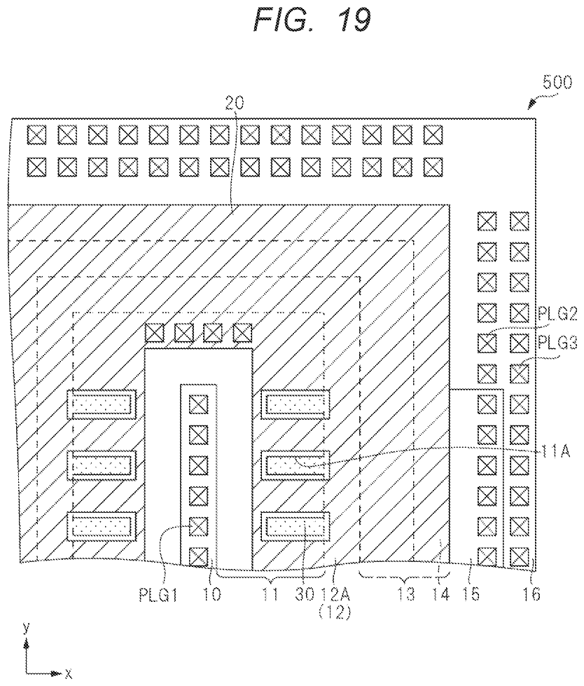

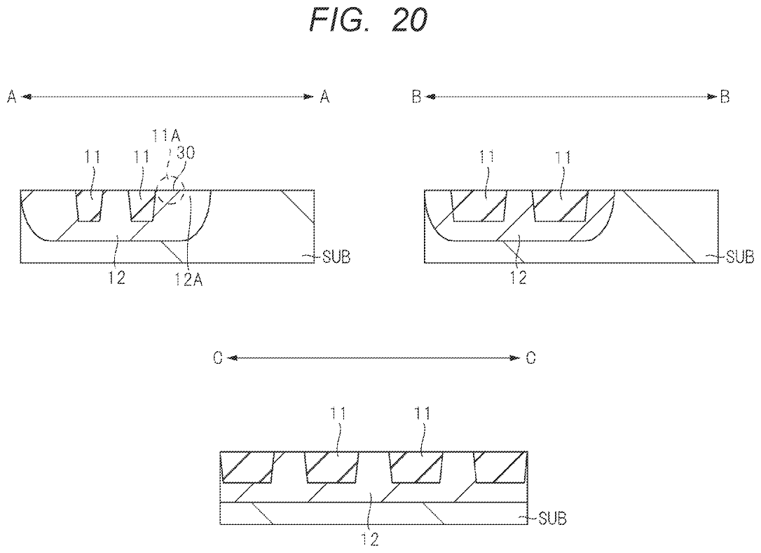

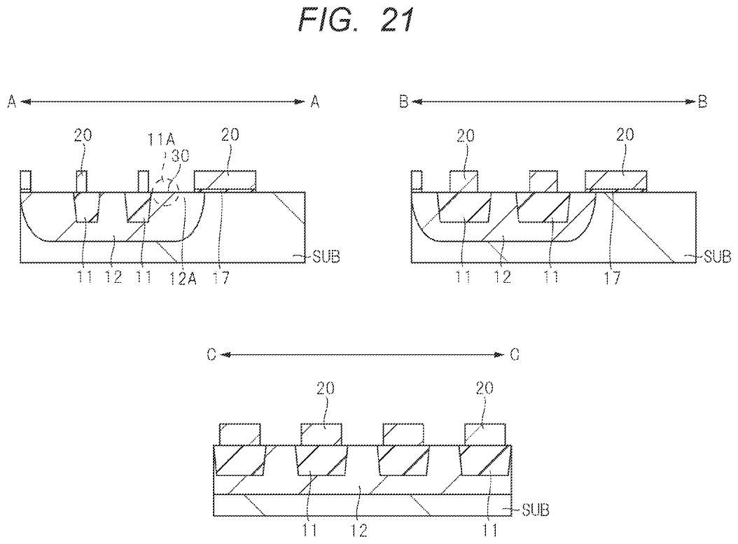

FIG. 19 is a figure showing a planar layout of an LDMOSFET 500 in the present fourth modified example. Here, for example, in the device in which improvement of the breakdown voltage is insufficient with only the second characteristic point, from the viewpoint of improving the breakdown voltage, for example, as shown in FIG. 19, it may be configured to employ only the first characteristic point, and as the embodiment shown in FIG. 8, it may be configured to employ a combination of the first characteristic point and the second characteristic point.

### Method of Manufacturing Semiconductor Device

Next, referring to FIGS. 20 to 26, a method of manufacturing a semiconductor device in the present embodiment will be described. In FIGS. 20 to 26, a cross-sectional view taken along line A-A in FIG. 8, a cross-sectional view taken along line B-B in FIG. 8, and a cross-sectional view taken along line C-C in FIG. 8 are shown.

First, as shown in FIG. 20, after the p⁻-type semiconductor substrate SUB is prepared, the “STI structure 11” is formed in the semiconductor substrate SUB. The “STI structure 11” can be formed, for example, by embedding a dielectric film in a trench after forming the trench in the surface of the semiconductor substrate SUB by using a photolithography technique and an etching technique. At this time, by adjusting the patterning at the time of forming the “STI structure 11”, the slit region 11A is formed in the “STI structure 11” (see a cross-sectional view taken along line A-A in FIG. 20). The drift region 12 exposed from the slit region 11A is the slit diffusion region 30.

N-type impurities (donors) are implanted into the semiconductor substrate SUB by using, for example, a photolithography technique and an ion implantation method. Thus, the drift region 12 formed of an n⁻-type semiconductor region is formed in the semiconductor substrate SUB.

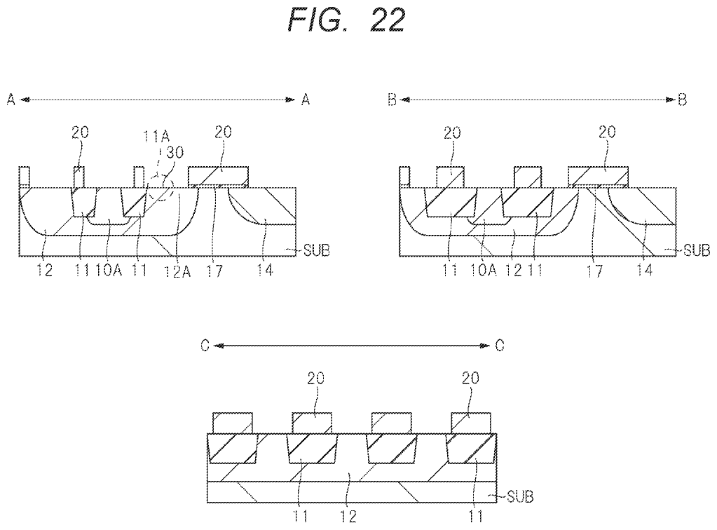

Next, as shown in FIG. 21, the gate dielectric film 17 and the gate electrode 20 are formed on the semiconductor substrate SUB. The gate dielectric film 17 is formed of a silicon oxide film, and can be formed by, for example, a thermal oxidation method. Further, the gate electrode 20 is formed of a polysilicon film, for example, and can be formed by patterning a polysilicon film using a photolithography technique and an etching technique after forming the polysilicon film by CVD method (Chemical Vapor Deposition). Here, as the connection region between the slit diffusion region 30 and the end region 12A of the drift region 12 is exposed from the gate electrode 20, the patterning of the polysilicon film is performed (see a cross-sectional view taken along line A-A in FIG. 21). Thus, the second characteristic point in the present embodiment, that the connection region between the slit diffusion region 30 and the end region 12A of the drift region 12 is exposed from the gate electrode 20, is realized.

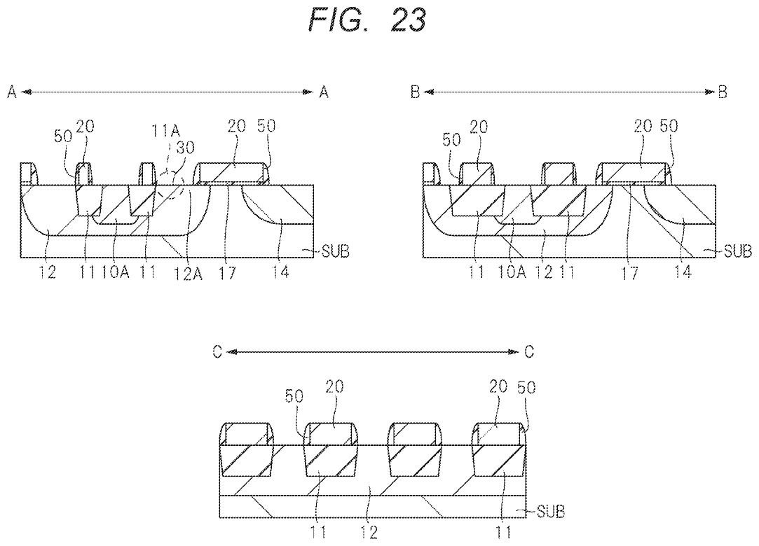

Subsequently, as shown in FIG. 22, n-type impurities (donors) are implanted into the semiconductor substrate SUB by using a photolithography technique and an ion implantation method. Thus, the buffer region 10A formed of an n-type semiconductor region included in the drift region 12 is formed.

Further, p-type impurities (acceptors) are implanted into the semiconductor substrate SUB by using a photolithography technique and an ion implantation method. Thus, the body region 14 formed of a p-type semiconductor region away from the drift region 12 is formed.

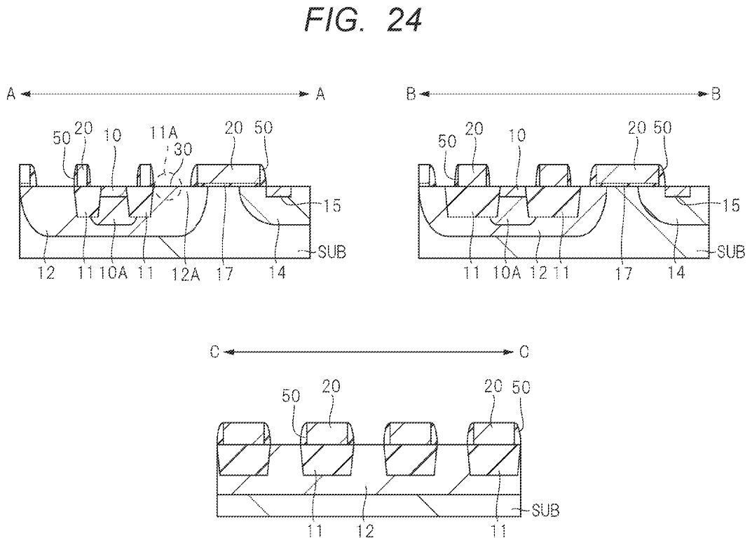

Thereafter, as shown in FIG. 23, sidewalls 50 are formed on the sidewalls of the gate electrode 20. For example, the sidewall 50 can be formed by performing anisotropic etching on a dielectric film after forming the dielectric film formed of a silicon oxide film or the like on the semiconductor substrate SUB.

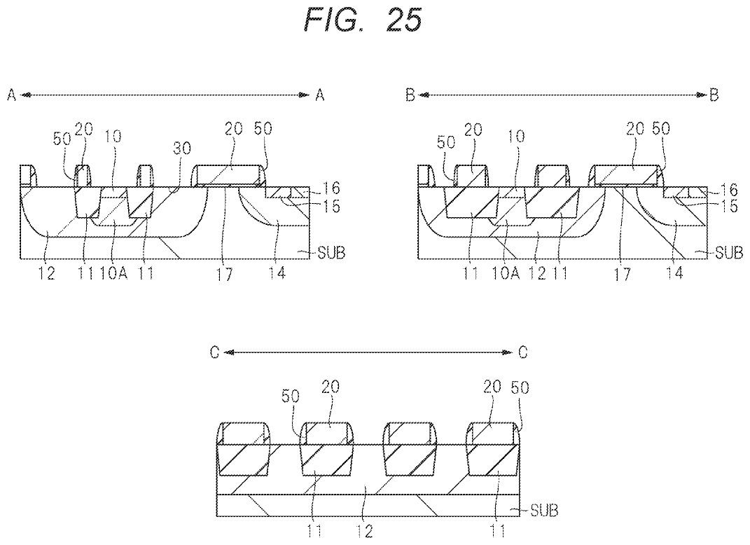

Next, as shown in FIG. 24, n-type impurities (donors) are implanted into the semiconductor substrate SUB by using a photolithography technique and an ion implantation method. Thus, the high concentration drain region 10 formed of an n⁺-type semiconductor region included in the buffer region 10A is formed. Similarly, n-type impurities (donors) are implanted into the semiconductor substrate SUB by using a photolithography technique and an ion implantation method. Thus, the source region 15 formed of an n⁺-type semiconductor region included in the body region 14 is formed.

Here, the slit diffusion region 30 is away from the high concentration drain region 10, and the first characteristic point in the present embodiment that a portion of the “STI structure 11” is interposed between the high concentration drain region 10 and the slit diffusion region 30 is realized.

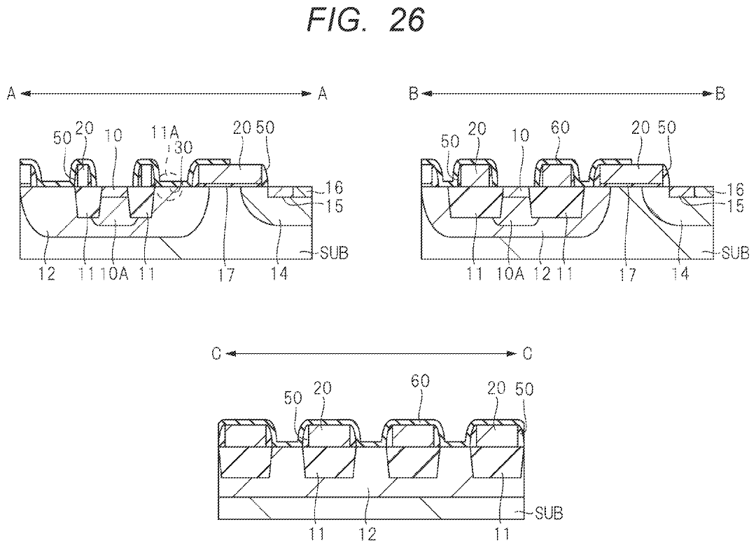

Subsequently, as shown in FIG. 25, p-type impurities (acceptors) are implanted into the semiconductor substrate SUB by using a photolithography technique and an ion implantation method. Thus, the body contact region 16 which is included in the body region 14 and is formed of a p⁺-type semiconductor region in contact with the source region 15 is formed.

Then, as shown in FIG. 26, by patterning a dielectric film by using a photolithography technique and an etching technique after forming the dielectric film on the semiconductor substrate SUB on which the gate electrode 20 is formed, a silicide block film 60 is formed. Thereafter, a silicide treatment is performed on the region not covered with the silicide block film 60.

Thereafter, wiring process is performed using conventional semiconductor fabrication techniques, although not shown.

As described above, the semiconductor device in the present embodiment can be manufactured.

The invention made by the present inventor has been described above in detail based on the embodiment, but the present invention is not limited to the embodiment described above, and it is needless to say that various modifications can be made without departing from the gist thereof.

For example, in the present embodiment, an example in which the “drain region” is configured by the high concentration drain region 10, the buffer region 10A (middle concentration drain region) and the drift region 12 (low concentration drain region) has been described, but the buffer region 10A may be omitted. That is, the “drain region” may be configured by the high concentration drain region 10 and the drift region 12.

Further, for example, as shown in FIG. 8, in the present embodiment, an example in which the source region 15 extending in the y-direction and the body contact region 16 extending in the y-direction are arranged side by side in the x-direction (channel direction) is shown, however, the basic idea in the present embodiment is not limited to this configuration, and for example, the basic idea can be applied to a configuration in which a plurality of source regions 15 extending in the x-direction and a plurality of body contact regions 16 extending in the x-direction are alternately arranged in the y-direction.

Further, in the present embodiment, the description has been made by taking the “STI structure 11” as an example of the isolation region, but the basic idea in the present embodiment is not limited to this structure, and the basic idea can be applied to, for example, the case where the “LOCOS structure” is employed as the isolation region.

Incidentally, for example, in FIG. 8, an example is shown in which it is “gate annular structure” that the gate electrode 20 surrounds the high concentration drain region 10 in plan view, the basic idea in the present embodiment is not limited to this configuration, and the basic idea can also be applied to the case of a “gate non-annular structure” that the gate electrode 20 does not surround the entire high concentration drain region 10 in plan view.

What is claimed is:

1. A semiconductor device, comprising:
a drain region;
a source region provided away from the drain region;
a channel region located between the drain region and the source region;
a gate dielectric film provided on the channel region;
a gate electrode provided on the gate dielectric film; and
an isolation region provided in the drain region,
wherein the drain region includes:
a high concentration drain region; and
a low concentration drain region including the high concentration drain region,
wherein the isolation region has a slit region extending in a first direction in plan view, and
wherein the isolation region is interposed between the slit region and the high concentration drain region in plan view.

2. The semiconductor device according to claim 1,
wherein the slit region is away from the high concentration drain region.

3. The semiconductor device according to claim 1,
wherein the isolation region includes a plurality of slit regions including the slit region, and
wherein the plurality of slit regions is arranged side by side in a second direction intersecting the first direction.

4. The semiconductor device according to claim 1,
wherein the slit region is exposed from the gate electrode.

5. The semiconductor device according to claim 1,
wherein a connection region between a source region side end portion of a slit diffusion region exposed from the slit region and the low concentration drain region is exposed from the gate electrode in plan view.

6. The semiconductor device according to claim 3,
wherein the plurality of slit regions is integrally exposed from the gate electrode in plan view.

7. The semiconductor device according to claim 3, comprising:
a plurality of conductor patterns arranged side by side in the second direction,
wherein each of the plurality of conductor patterns is arranged between two of the plurality of slit regions adjacent to each other in the second direction in plan view.

8. The semiconductor device according to claim 7,
wherein the each of the plurality of conductor patterns is electrically connected to the gate electrode via a plug.

9. A semiconductor device, comprising:
a drain region;
a source region provided away from the drain region;
a channel region located between the drain region and the source region;
a gate dielectric film provided on the channel region;
a gate electrode provided on the gate dielectric film; and
an isolation region provided in the drain region,
wherein the drain region includes:
a high concentration drain region; and
a low concentration drain region including the high concentration drain region,
wherein the isolation region has a slit region extending in a first direction in plan view, and
wherein a connection region between a source region side end portion of a slit diffusion region exposed from the slit region and the low concentration drain region is exposed from the gate electrode in plan view.

10. The semiconductor device according to claim 9,
wherein the isolation region is interposed between the slit region and the high concentration drain region in plan view.
